(19) United States
(12) Patent Application Publication
(10) Pub. No.: US 2006/0170022 A1
(43) Pub. Date: Aug. 3, 2006

(54) Silicon molecular hybrid storage cell

(76) Inventor: Klaus Ufert, Unterschleissheim (DE)

Correspondence Address: DICKE, BILLIG & CZAJA, P.L.L.C., FIFTH STREET TOWERS, 100 SOUTH FIFTH STREET, SUITE 2250, MINNEAPOLIS, MN, 55402, US

(21) Appl. No.: 11/047,199

(22) Filed: Jan. 31, 2005

(51) Int. Cl. H01L 29/94; H01L 51/40

(52) U.S. Cl. 257/296; 438/99

(57) ABSTRACT

Semiconductor molecular hybrid element with a storage cell comprising, arranged between a first and a second electrode, a layer of a self-assembled monolayer made of an organic compound, whereby the organic compound is a compound corresponding to the general formula I or II 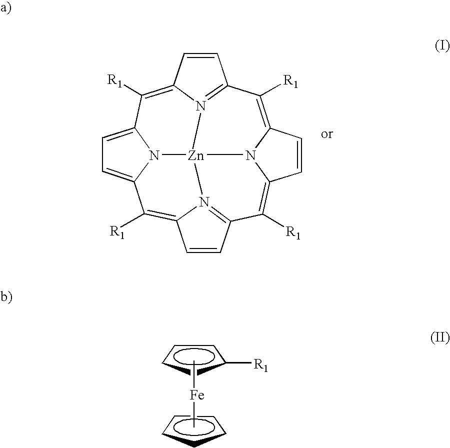 whereby R1 represents hydrogen, an alkyl chain with 1-20 C atoms, an aromatic group that can be substituted by an alkyl chain with 1-4 C atoms or by one or several functional groups,
whereby at least one R1 group in the general formula I or II is an anchoring group corresponding to the formula 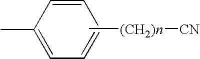 and whereby n is an integer in the range from 1-4.

### FIELD OF THE INVENTION

The invention relates to a semiconductor molecular hybrid element whose storage operates based on resistivity.

### BACKGROUND

One of the essential aims in the further development of modern storage technologies is to increase the integration density such that the reduction of the structural sizes of the storage cells on which the storage facilities are based possesses great significance. Moreover, it is aimed to develop new storage cells which can be switched at low voltage.

In recent years, several microelectronic elements and, in particular, storage cells of a size of but a few nanometers have been described. According to one concept for the set-up of such storage cells an active layer is adjusted between two electrodes, which active layer can change reversibly certain properties, for example ferroelectric or magnetic properties or electric resistance. Depending on the voltage applied, the cell can be switched between two stable states such that one state can be assigned for example to the informational state “0” and the other state can be assigned to the informational state “1”.

Moreover, various storage cells with an active layer have been described, which vary their properties depending on the voltage applied, which causes the conductivity of the storage cell to change such that two or more different stable states can be formed.

The cell comprising between two electrodes an active layer capable of changing its electric resistance depending on the voltage applied is advantageous when compared to the cells containing between two electrodes a ferroelectric material in that it has a much larger signal ratio for the OFF versus the ON state and does not need to be rewritten after the read operation, since the reading of the state is not destructive.

The invention relates to a semiconductor molecular hybrid element with a first and a second electrode and a monomolecular storage layer arranged in between the first and the second layer.

One of the essential aims in the further development of modern storage memory technologies is to increase the integration density such that the reduction of the structural sizes of the memory cells possesses great significance.

The proposed elements usually comprise a molecular layer (monolayer) arranged between two electrodes. Preferably, the monolayers are formed self-assembling on a suitable substrate. In an ideal case, elements of this type can be reduced in size to the order of magnitude of the molecular level of approx. 0.5 to 5 nm. In general a limited number of individual molecules (100, for example) is used for the fabrication of one storage function. Preferably, these molecules are arranged in a passive matrix or in an assembly of molecules, whereby, in each crossing point of the passive matrix, an assembly of molecules forms the storage function.

The previous literature includes a number of description of self-assembled monolayers that are potentially suitable as active layers in semiconductor molecular hybrid elements.

Almost all previously described concepts preferably use one or several thiol (—SH) anchoring group(s) with or without linker for fixing the molecule to the surface of the electrode. For this reason, gold is always used as electrode material. However, since the gold/thiol system often fails to have a covalent bond between the thiol/thiolate and the gold atoms, but rather the self-assembling effect is based mainly on the lowering of the configurational entropy, this system is stable only to a limited degree. Thus, for example, self-assembled monolayers with thiol anchoring groups on gold surfaces are not stable with regard to the impact of various organic and inorganic solvents.

Moreover, the use of gold as electrode material for the bottom electrode in silicon-CMOS processes is problematic, since gold residing in close proximity to the semiconductor silicon is a dangerous dopant. In terms of process technology, the use of gold as the bottom electrode is therefore undesirable. The use of gold as material for the top electrode is less critical, since the top electrode is deposited significantly later in the process. Nevertheless, it is desirable to use metals, such as aluminum, Ti, Pt, Pd or Au, for the top electrode.

As active layers, self-assembled monolayers of Zn-porphyrin or ferrocene compounds binding to the silicon substrate via an —OH group (from a PO₃H-group) have been proposed in Li et al.: Applied Physics Letters, Vol. 85 (10), 2004, p. 182 and Li et al.: Applied Physics Letters, Vol. 83 (1), 2003, p. 198. These documents are herewith incorporated by reference. The synthesis and the properties of Por-SH derivatives has been described in D. T. Gryko, C. Clausem, J. S. Lindsay, J. Org. Chem. vol. 64, (1999), p. 8635.

Hereinafter, the terms “porphyrin” and “ferrocene” shall be abbreviated by “Por” and “Fc”, respectively.

The abbreviation, “Bz”, may denote either a benzyl group (—CH₂C₆H₄—) or a phenyl group (—C₆H₄—).

With regard to the integration of organic storage molecules into existing CMOS platforms, the OH— and SH— molecule groups discussed in the literature provide solutions only to a limited degree. The essential disadvantage of these weakly bound molecule groups is that both the electron transfer characteristics and the barrier effect of the OH—O—Si interfacial layer next to the silicon substrate cannot be controlled or adjusted optimally.

Consequently, neither the retention nor the programming or erase time of a silicon-molecular hybrid storage element are in a useful range reproducible, as well.

### SUMMARY

According to one embodiment of the invention it is proposed to arrange between a first and a second electrode in the form of a self-assembled monolayer an organic compound selected from the group consisting of the compounds corresponding to the general formula I or II

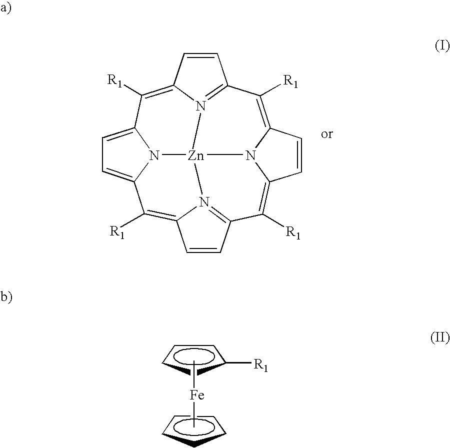

whereby R1 represents hydrogen, an alkyl chain with 1-20 C atoms, an aromatic group that can be substituted by an alkyl chain with 1-4 C atoms or by one or several functional groups,

whereby at least one R1 group in the general formula I or II is an anchoring group corresponding to the formula

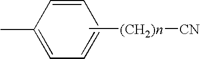

and

whereby n is an integer in the range from 1-4. Hereinafter, the CN group shown above shall also be referred to as “anchoring group”.

The compounds described above corresponding to the general formula I or II form, in a substrate-specific fashion, strongly ordered monolayers with a silicon-containing electrode. The silicon-containing electrode can also comprise a thin native oxide layer without impairing the function of the semiconductor molecular hybrid element.

In the simplest embodiment of the invention, the storage cell, which is housed in a semiconductor molecular hybrid element, consists of two electrodes and one self-assembled molecular layer comprising an organic compound corresponding to the general formula I or II.

The organic compound is deposited selectively to the lower electrode in a self-assembled monolayer such that there is no lithographic step involved. The deposition and the structuring of the upper electrode (top electrode) can be performed using standard technologies, for example thermal evaporation and photolithography. In the process, the self-assembled monolayer can be bound directly to the top electrode with the active center being in electric contact to the top electrode.

Therefore, in a particular embodiment of the invention, a head group binding the molecular complex to the top electrode is provided. The head group binds covalently to the Por or Fc redox-center. At the other side between Por and Fc redox-center an anchoring group and a linker is provided.

This allows to stabilize the storage effect over a certain time, otherwise the charge retention is too poor for many applications. In this, the length of the linker chain can be designed such that the chain prevents a direct contact between the active center, an anchoring group, and the electrode, but provides for electric tunneling without problems. Additionally, the selection of the length of the linker units can be used to adjust the programming and the retention time of the cells within certain limits.

In a particular embodiment, the linker group is selected from the group consisting of n-alkyl with 4 to 40 C atoms, aryl groups, such as for example biphenyl, triphenyl, tetraphenyl, or alkyl(thio)ether groups.

The head group, if any, serves to mediate the binding to the top electrode in order to fix the organic compound both to the upper electrode. This allows the arrangement to attain higher chemical, thermal or mechanical stability.

The particularly preferred embodiment provides as the head group a residue selected from the group consisting of SH, OH, NH₂, COOH, CONH₂. CONHOH, CONHNH₂, NHR, NR₂ or PR₃.

The substrate onto which the electrodes were applied or in which the electrodes were incorporated can be made of silicon, germanium, or any material containing silicon.

The substrate can also be made of a previously processed material and contain one or several layers of contacts, printed conductors, insulating layers, and other microelectronic components. The electric contacts can for example be contact holes (Vias) filled with an electric conductor. However, it is possible that the contacts are implemented from lower to the upper layers by metallizing the edges of the substrate or chips.

In a preferred embodiment, the substrate is made of silicon and the first (bottom) electrode is also silicon-containing. The first electrode preferably consists of doped silicon.

The self-assembled monolayer of the organic compound according to the invention corresponding to general formula I or II is compatible with a multitude of electrodes commonly used in electronics devices.

The upper (top) electrode preferably consists of gold (Au), silver (Ag), platinum (Pt), palladium (Pd), aluminum (Al), titanium (Ti), titanium nitride (TiN), tantalum (Ta), iridium (Ir), as well as common combinations of these electrodes. Moreover, thin layers made of silicon can be present in combination with the layers or materials mentioned above.

The abbreviations, for example TiN, do not reflect the exact stoichiometric ratios, since the ratio of the components can be changed freely within the possible existing limits.

Various procedures are suitable for deposition of the top electrode layers mentioned above. These can include for example evaporation, CVD, PECVD, or Atomic Layer Deposition (ALCVD). However, the methods are not limited to these and basically all procedures used in microelectronics for the manufacture of electrodes can be used.

The electrode can be deposited from the solid or from the gas phase.

The top electrode can be structured by means of various common techniques. The structuring can be effected for example by means of shadow masks, printing techniques or lithography. Screen printing, micro-contact printing or nano-imprinting are particularly preferred as printing techniques.

In a preferred embodiment of the invention, the upper electrode is arranged transverse to the lower electrode. This generates at each crossing point of the upper electrode and the lower electrode a so-called crossing point cell which consists of at least three layers, namely lower electrode, active material, and upper electrode.

The lateral geometry of the cell is not limited to the crossing point arrangement mentioned above, but since the crossing point arrangement affords a very high integration density, it is preferred for the present invention.

The semiconductor molecular hybrid element according to the present invention can comprise several of the storage cells described above. In a preferred embodiment of the invention, the semiconductor molecular hybrid element comprises several mutually crossing word and bit lines such that the cells reside at the crossing points of the word and bit lines (“crossing point” cell). In this case, the storage cells are arranged in the semiconductor molecular hybrid element as a matrix, whereby this matrix extends both in the XY plane and in the XZ plane.

The arrangement of several cells in one matrix corresponds to the arrangement of ferroelectric or magnetic storage devices and is known to the expert in the field. The crossing point cells can be fabricated either by depositing the monolayer on the bottom electrode directly after the structuring of the bottom electrode or by first structuring the bottom electrode, then depositing a dielectric layer (field dielectric) on the bottom electrode, and defining contact holes in which the storage material (the organic compound) is deposited. Subsequently, the counter-electrode (top electrode) is defined orthogonal to the bottom electrode.

The possibilities of arranging the storage cells are described for example in DE 103 55 561.7. During the fabrication of the storage cells according to the invention it is only necessary to ensure that the thickness of the field dielectric is approximately equal to the length of the molecules forming the self-assembled monolayer. The cell structure is particularly well-suited for the fabrication of staggered arrays.

### BRIEF DESCRIPTION OF THE DRAWINGS

The accompanying drawings are included to provide a further understanding of the present invention and are incorporated in and constitute a part of this specification. The drawings illustrate the embodiments of the present invention and together with the description serve to explain the principles of the invention. Other embodiments of the present invention and many of the intended advantages of the present invention will be readily appreciated as they become better understood by reference to the following detailed description. The elements of the drawings are not necessarily to scale relative to each other. Like reference numerals designate corresponding similar parts.

FIG. 1 illustrates a schematic depiction of the organic compound forming the self-assembled monolayer.

FIG. 2 illustrates a schematic depiction of the attachment of the cyanide group of a Fc-BzCN- or Zn-Por-BzCN compound to a Si-substrate surface covered by native oxide.

FIG. 3 illustrates a schematic depiction of the layer structure of a silicon/ferrocene or silicon/Zn-porphyrin hybrid storage cell.

FIG. 4 illustrates a symbolic depiction of the Por or Fc hybrid memory cell according to the present invention.

FIG. 5 illustrates symbolic depiction of the Por or Fc semiconductor hybrid memory cell.

### DETAILED DESCRIPTION

In the following Detailed Description, reference is made to the accompanying drawings, which form a part hereof, and in which is shown by way of illustration specific embodiments in which the invention may be practiced. In this regard, directional terminology, such as “top,” “bottom,” “front,” “back,” “leading,” “trailing,” etc., is used with reference to the orientation of the Figure(s) being described. Because components of embodiments of the present invention can be positioned in a number of different orientations, the directional terminology is used for purposes of illustration and is in no way limiting. It is to be understood that other embodiments may be utilized and structural or logical changes may be made without departing from the scope of the present invention. The following detailed description, therefore, is not to be taken in a limiting sense, and the scope of the present invention is defined by the appended claims.

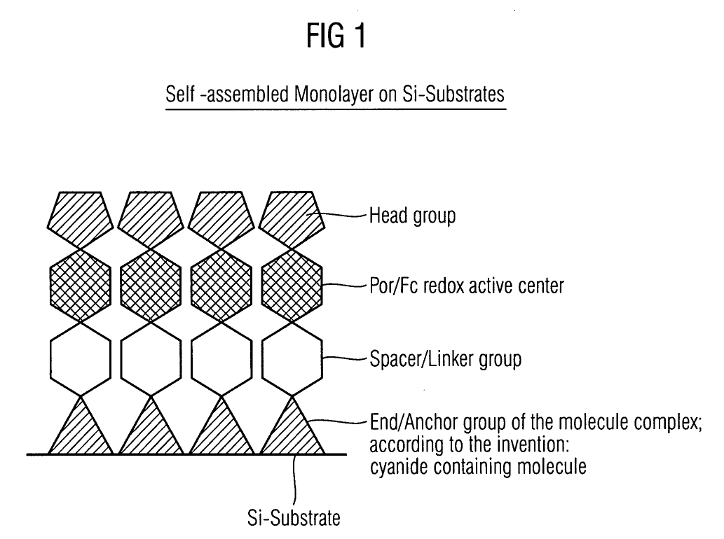

FIG. 1 illustrates a particularly preferred embodiment, whereby the organic compound forms a self-assembled monolayer between the first (bottom) electrode and the second (top) electrode.

In this preferred embodiment, the organic compound consists of a CN-anchoring group, a head group and a Zn-Por or Fc redox-center arranged between these. The CN-anchoring group binds to the bottom electrode made of silicon and the head group binds to the top electrode. The active redox-center made of Zn-Por or Fc resides in the middle between the top electrode and the bottom electrode.

In this embodiment, three linker groups are described which spatially separate the redox-center from the bottom electrode in order to achieve a stabilization of the storage effect over time.

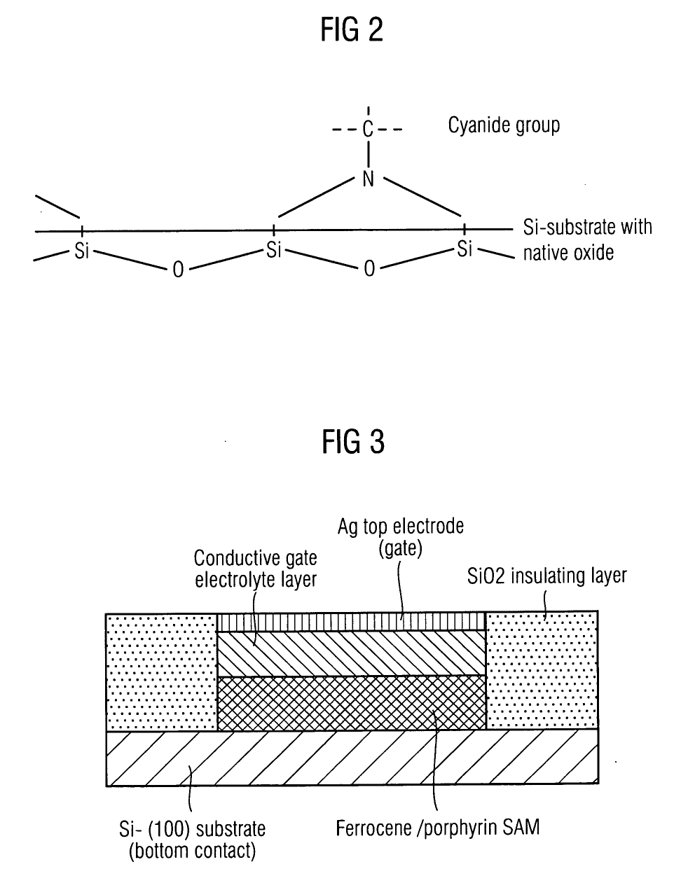

FIG. 2 illustrates one embodiment of a schematic depiction of the attachment of the cyanide group of a Fc-BzCN or Zn-Por-BzCN compound to a Si-substrate surface covered with native oxide. An oxide layer is not really desirable even though a thin oxide layers does not generally impair the function of the cell according to the invention. As is in FIG. 2, some free valences remain at the surface for the nitrogen of the CN anchoring group such that a monolayer can be formed.

FIG. 3 illustrates one embodiment of a storage cell according to the invention, which contains between the first electrode (bottom electrode) made of silicon and the second electrode (top electrode) made of silver a monolayer made of the organic compound corresponding to the general formula I or II. This set-up requires structuring of the self-assembled monolayer according to the invention made of the organic compound in order for the deposition to be substrate-specific and to lead to the entire bottom electrode made of silicon being covered.

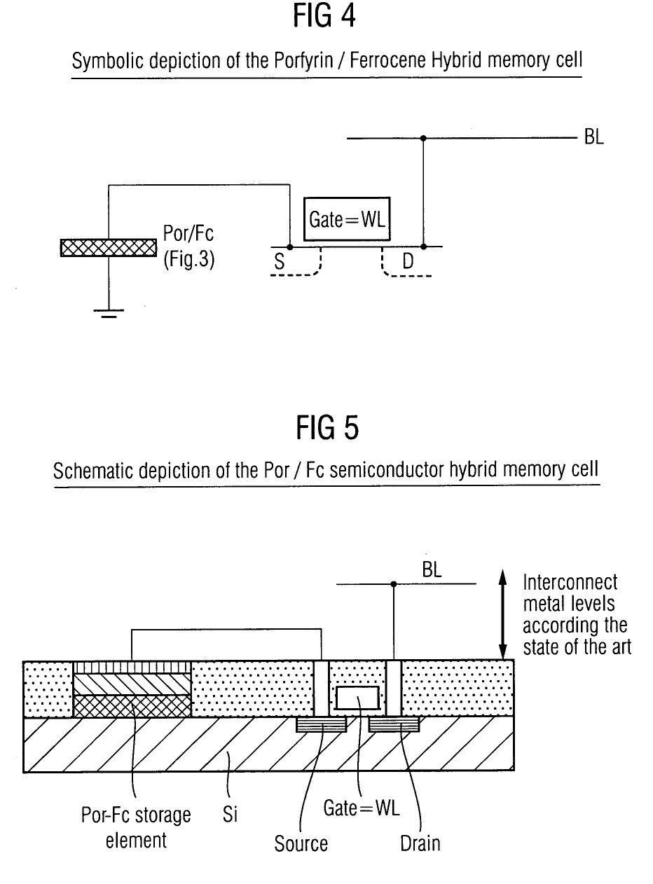

FIG. 4 illustrates one embodiment of a symbolic depiction of the Por or Fc hybrid memory cell according to the present invention and the arrangement of such a cell between a word and a bit line.

FIG. 5 illustrates one embodiment of symbolic depiction of a possible arrangement of the Por or Fc semiconductor hybrid memory cell.

### MANUFACTURING EXAMPLE

A p-Si (100) wafer, processed with functionalized CMOS technology according to the state of the art (schematically shown in FIGS. 4 and 5) is covered by a thermally grown or deposited (for example by thermal ICVD with TEOS) SiO2 layer.

Following a lithographic step, a hole or a structure is etched into this SiO2 layer down to the Si-substrate. The etching step can be performed for example by means of reactive plasma etching using CF4 as etching gas.

The thus structured Si-substrate is then placed in a solution consisting of 1 mg Fc-BzCN or Zn-Por-BzCN dissolved 200 μl of benzonitrile. The temperature of the substrate is between 60° C. and approx. 100° C. and the substrate is kept in the solution for at least 30 minutes while the attachment process of the ferrocene or Zn-porphyrin molecule monolayer proceeds. Then the substrate coated with the ferrocene or Zn-porphyrin storage molecule is rinsed with a suitable liquid and dried in a stream of anhydrous N2 gas.

Subsequently a solution of 1.0 M tetrabutylammonium hexafluorophosphate in propylenecarbonate is applied under a normal atmosphere to serve as conducting gate electrolyte. Finally, a silver top contact is applied to contacting gate electrolyte (for example Nafion®) by means of thermal evaporation or electron beam evaporation in a vacuum.

Although specific embodiments have been illustrated and described herein, it will be appreciated by those of ordinary skill in the art that a variety of alternate and/or equivalent implementations may be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

What is claimed is:

1. A memory cell comprising:
a first electrode;
a second electrode; and
a layer of a self-assembled monolayer of an organic compound arranged between the first and the second electrode, wherein the organic compound is a compound corresponding to the general formula I or II 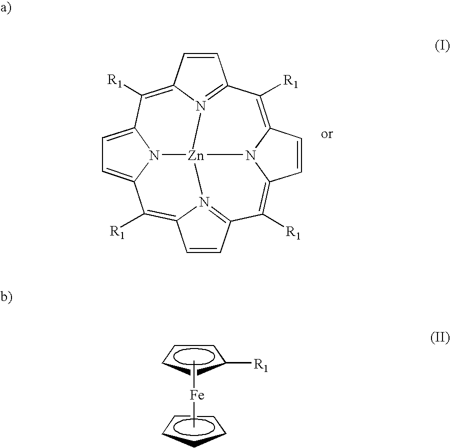
whereby R1 represents hydrogen, an alkyl chain with 1-20 C atoms, an aromatic group that can be substituted by an alkyl chain with 1-4 C atoms or by one or several functional groups,
whereby at least one R1 group in the general formula I or II is an anchoring group corresponding to the formula 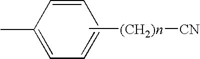
and
whereby n is an integer in the range from 1-4.

2. The memory cell according to claim 1, wherein
the organic compound comprises a head group.

3. The memory cell according to claim 2, wherein the head group is selected from the group consisting of —SH, —OH, —NH₂, —NHR, —NR₂, —PHR, —PR₂, —COOH, —CONH₂, —CONHOH, and —CONHNH₂.

4. The memory cell according to claim 1, wherein the first electrode is silicon-containing.

5. The memory cell according to claim 1, wherein the second electrode is selected from the group consisting of gold (Au), silver (Ag), platinum (Pt), palladium (Pd), aluminum (Al), titanium (Ti), titanium nitride (TiN), tantalum (Ta), iridium (Ir), as well as common combinations of these electrodes or is a combination of these layers and/or materials and, if applicable, in addition is provided with a layer made of silicon (Si).

6. The memory cell according to claim 1, whereby the semiconductor molecular hybrid element comprises a word and a bit line such that the first electrode is a part of the bit line and the second electrode is a part of the word line, whereby the storage cell is arranged between the crossing word and bit lines.

7. The memory cell according to claim 1, characterized in that several storage cells are present, which form a matrix.

8. The memory cell according to claim 7, characterized in that
the storage cells are present in the XY, YZ, and XZ planes.

9. Method for the manufacture of a semiconductor molecular hybrid element comprising the following steps:
provision of a substrate;
provision of a first electrode;
contacting the first electrode with an organic compound corresponding to the general formula I or II. 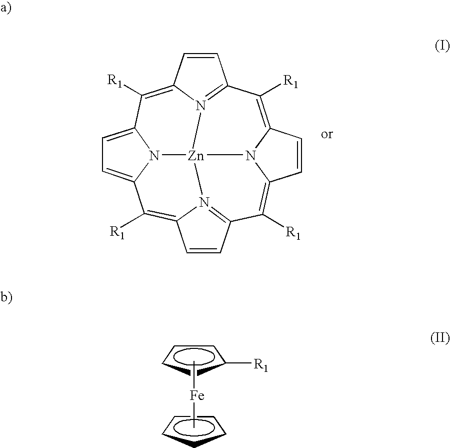
whereby R1 represents hydrogen, an alkyl chain with 1-20 C atoms, an aromatic group that can be substituted by an alkyl chain with 1-4 C atoms or by one or several functional groups,
whereby at least one R1 group in the general formula I or II is an anchoring group corresponding to the formula 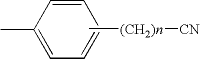
and
whereby n is an integer in the range from 1-4,
whereby a self-assembled monolayer is formed;
deposition of the second electrode.
